(19) United States
(12) Patent Application Publication
(10) Pub. No.: US 2007/0023802 A1
(43) Pub. Date: Feb. 1, 2007

(54) CMOS image sensor and method of fabricating the same

(75) Inventors: Tae-Seok Oh, Seoul (KR); Jae-Ho Song, Suwon-si (KR); Jung-Ho Park, Seoul (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/493,146

(22) Filed: Jul. 26, 2006

(30) Foreign Application Priority Data
Jul. 26, 2005 (KR) 10-2005-0068036

(51) Int. Cl. H01L 31/113; H01L 31/062

(52) U.S. Cl. 257/292

(57) ABSTRACT

In a CMOS image sensor and method of fabricating the same, the CMOS image sensor is comprised of a pixel array generating image signals and a peripheral circuit processing the image signals. In the method, a substrate is provided having a pixel region and a peripheral circuit region. A photo-receiving element and at least one transistor are formed on the pixel region of the substrate and a transistor is formed on the peripheral circuit region of the substrate. A silicide barrier pattern is formed to cover a region where the photo-receiving element is formed. A silicide layer is formed on a predetermined region of the substrate. An interlevel insulation film is formed on the silicide barrier layer. At least one contact hole penetrating the interlevel insulation film is formed, the at least one contact hole exposing a predetermined region of the silicide layer. This is effective to prevent a problem such as an excessive etching due to disagreement of the etch target films between the pixel array and the peripheral circuit.

### CROSS-REFERENCE TO RELATED APPLICATIONS

This U.S. non-provisional patent application claims priority under 35 U.S.C. § 119 to Korean Patent Application 10-2005-0068036 filed on Jul. 26, 2005, the contents of which are incorporated herein by reference in their entirety.

### BACKGROUND

The subject matter described herein relates to image sensors and particularly to a CMOS image sensor and method of fabricating the same.

Image sensors are photoelectrical devices that are used to convert optical images into electrical signals by employing the characteristic response of semiconductor materials to incident light. Image sensors can be generally classified as charge-coupled devices (CCD) and complementary metal-oxide-semiconductor (CMOS) devices. CMOS image sensors usually have the same number of photo-receiving and switching elements as the number of pixels, by which optical images are output as electrical signals. The CMOS image sensor enjoys simpler operation than the CCD image sensor, which is advantageous for miniaturization because it can be integrated onto a single chip with corresponding signal processing circuitry. The CMOS image sensor also consumes relatively low battery power and is thus well suited for operation in portable devices. With the further development of CMOS processing technologies and advancement of signal processing algorithms, several limitations of CMOS image sensors have been overcome. Recently, the demand for CMOS image sensors has highly increased with the ever-increasing popularity of portable devices such as mobile phones and digital cameras.

A typical CMOS image sensor includes a pixel array composed of pixels that sense light to generate electrical signals, and a peripheral circuit processing the electrical signals. The pixel and peripheral circuit employ semiconductor devices such as MOS transistors, which are required to form a silicide layer on a specific region of the semiconductor device and thereby to lower resistance of the corresponding region, to achieve high integration density and high speed operation. For instance, a metal silicide layer may be formed on a source or a drain region, or on a gate electrode of the MOS transistor.

A pixel of the CMOS image sensor is comprised of a photo-receiving element, i.e., a photodiode, which generates electron-hole pairs in response to light. In this case, it may not be preferred to form a metal silicide layer on the photodiode, because the metal silicide layer may degrade optical quality of the photodiode, prohibiting transmission of light having a short wavelength such as blue light, which lessens light intensity therein, and operating as a source of dark current even in the absence of incident light. In view of this, a silicide protection layer is placed on the pixel area before forming the silicide layer on other regions of the device for example in the peripheral circuit area of the device.

As processing steps for fabricating the CMOS image sensor are simultaneously carried out on the areas of the pixel array and peripheral circuit, problems can arise from the differences in morphology and material between the regions during subsequent fabrication procedures following formation of the silicide protection layer exclusively in the pixel array area. For example, in the case of forming contacts for semiconductor elements arranged in the pixel array and peripheral circuit, first, in forming contacts on source regions of the MOS transistors, an interlevel insulation layer on the source regions is patterned to form contact holes. Here, on the source regions of the pixel array area are disposed a silicide barrier layer and an interlevel insulation film, while, on the source regions of the peripheral circuit area, only the interlevel insulation film is disposed. Because of structural differences and component differences in those regions, over-etching in the peripheral circuit area can result during etching the silicide layer of the pixel array area. As a result, such an asymmetric etching profile over the pixel and peripheral areas can adversely affect operational characteristics of the CMOS image sensor.

### SUMMARY OF THE INVENTION

Exemplary embodiments of the present invention provide a CMOS image sensor and method of fabricating the same, which improves operational characteristics thereof.

In one aspect, the present invention is directed to a method of fabricating a CMOS image sensor comprising: providing a substrate having a pixel region and a peripheral circuit region; forming a photo-receiving element and at least one transistor on the pixel region of the substrate and forming a transistor on the peripheral circuit region of the substrate; forming a silicide barrier pattern to cover a region where the photo-receiving element is formed; forming a silicide layer on a predetermined region of the substrate; forming an interlevel insulation film on the silicide barrier pattern; and forming at least one contact hole penetrating the interlevel insulation film, the at least one contact hole exposing a predetermined region of the silicide layer.

In one embodiment, the forming the silicide barrier layer pattern in the pixel region comprises: depositing a silicide barrier layer on the substrate; and removing the silicide barrier layer formed in at least one region where the at least one contact hole is formed.

In another embodiment, the step of forming the silicide barrier layer pattern in the pixel region comprises: depositing a silicide barrier layer on the substrate; and removing the silicide barrier layer formed in at least one region where the at least one contact hole is formed in a unified portion.

In another embodiment, the photo-receiving element is a photodiode.

In another embodiment, the step of forming the silicide barrier pattern in the peripheral circuit region comprises: depositing a silicide barrier layer on the substrate; and removing the silicide barrier layer pattern in an active region and a region where a gate electrode of the transistor is formed.

In another embodiment, the silicide barrier layer pattern includes a nitride film.

In another aspect, the present invention is directed to a method of fabricating a CMOS image sensor comprising: providing a substrate having a pixel region and a peripheral circuit region; forming a transfer gate electrode on the substrate of the pixel region; forming a photo-receiving element at a side of the transfer gate electrode; forming a floating diffusion region at a side of the transfer gate electrode opposite the photo-receiving element; forming a silicide barrier layer pattern on the photo-receiving element; forming a first silicide layer on a portion of the floating diffusion region; and forming an interlevel insulating layer on the silicide barrier layer pattern and the transfer gate electrode, the interlevel insulating layer having a contact hole exposing a portion of the first silicide layer.

In one embodiment, the photo-receiving element and the floating diffusion region are formed in the substrate of the pixel region.

In another embodiment, the silicide barrier layer pattern extends across the transfer gate electrode.

In another embodiment, the method further comprises forming a gate dielectric layer between the transfer gate electrode and the substrate.

In another embodiment, the silicon barrier layer pattern comprises a silicon nitride film.

In another embodiment, the method further comprises forming a second silicide layer on the transfer gate electrode.

In another embodiment, the method further comprises forming at least one transistor on the peripheral circuit region, the transistor having a drain, a source, and a gate electrode.

In another embodiment, the method further comprises forming a third silicide layer on surfaces of the source, drain, and gate electrodes.

In another aspect, the present invention is directed to a CMOS image sensor comprising: a substrate having a pixel region with a first and a second region and a peripheral circuit region; a photo-receiving element on the first region of the substrate; at least one transistor including an active region connected to the photo-receiving element on the second region of the substrate; a silicide barrier layer formed on the first region of the substrate; a silicide layer formed on a portion of the second region of the substrate; an interlevel insulation layer covering the silicide barrier layer and the first and second regions of the substrate and having at least one contact hole penetrating the interlevel insulation layer, the contact hole exposing a portion of the silicide layer.

In one embodiment, the contact hole is formed in a impurity diffusion region of the transistor in the active region.

In another embodiment, the at least one contact hole is formed on a gate electrode of the transistor.

In another embodiment, the at least one contact hole is formed in plurality and the silicide layer is formed in plural separated regions of the second region.

In another embodiment, the at least one contact holes is formed in plurality and the silicide layer is formed in a unified region that includes the plurality of contact holes.

In another embodiment, the photo-receiving element is a photodiode.

In another embodiment, the image sensor further comprises at least one transistor processing a signal that is transferred from the pixel region in the peripheral circuit region.

In another embodiment, the silicide layer in the peripheral circuit region is formed in an active region and a region where a gate electrode of the transistor is formed.

In another embodiment, the silicide barrier layer comprises a nitride film.

In another aspect, the present invention is directed to a CMOS image sensor comprising: a substrate having a pixel region and a peripheral circuit region; a transfer gate electrode on the substrate of the pixel region; a photo-receiving element at a side of the transfer gate electrode; a floating diffusion region at a side of the transfer gate electrode, opposite the photo-receiving element; a silicide barrier layer pattern on the photo-receiving element; a first silicide layer on a portion of the floating diffusion region; and an interlevel insulating layer on the silicide barrier layer pattern and the transfer gate electrode, the interlevel insulating layer having a contact hole exposing a portion of the first silicide layer.

In one embodiment, the photo-receiving element and the floating diffusion region are disposed in the substrate of the pixel region.

In another embodiment, the silicide barrier layer pattern extends across the entire surface of the transfer gate electrode.

In another embodiment, the image sensor further comprises a gate dielectric layer between the transfer gate electrode and the substrate.

In another embodiment, the silicon barrier layer pattern comprises a silicon nitride film.

In another embodiment, the image sensor further comprises a second silicide layer on the transfer gate electrode.

In another embodiment, the image sensor further comprises at least one transistor on the peripheral circuit region, the transistor having a drain, a source, and a gate electrode.

In another embodiment, the image sensor further comprises a third silicide layer on surfaces of the source, drain, and gate electrodes.

### BRIEF DESCRIPTION OF THE DRAWINGS

The foregoing and other objects, features and advantages of the invention will be apparent from the more particular description of preferred embodiments of the invention, as illustrated in the accompanying drawings in which like reference characters refer to the same parts throughout the different views. The drawings are not necessarily to scale, emphasis instead being placed upon illustrating the principles of the invention. In the drawings:

FIG. 1 is a plan view illustrating a CMOS image sensor in accordance with an embodiment of the invention;

FIG. 2 is an equivalent circuit view showing the pixel region shown in FIG. 1;

FIG. 3 is a sectional view taken along lines I-I′ and II-II′ of FIG. 1;

FIGS. 4 through 8 are sectional views illustrating processing steps for fabricating the CMOS image sensor in accordance with an embodiment of the invention; and

FIGS. 9A and 9B are plan views illustrating CMOS image sensors in accordance with other embodiments of the invention.

### DETAILED DESCRIPTION OF PREFERRED EMBODIMENTS

Preferred embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete. In the figures, the dimensions of layers and regions are exaggerated for clarity of illustration. It will also be understood that when a layer (or film) is referred to as being ‘on’ another layer or substrate, it can be directly on the other layer or substrate, or intervening layers may also be present. Like reference numerals refer to like elements throughout.

Hereinafter, an exemplary embodiment of the present invention will be described in conjunction with the accompanying drawings.

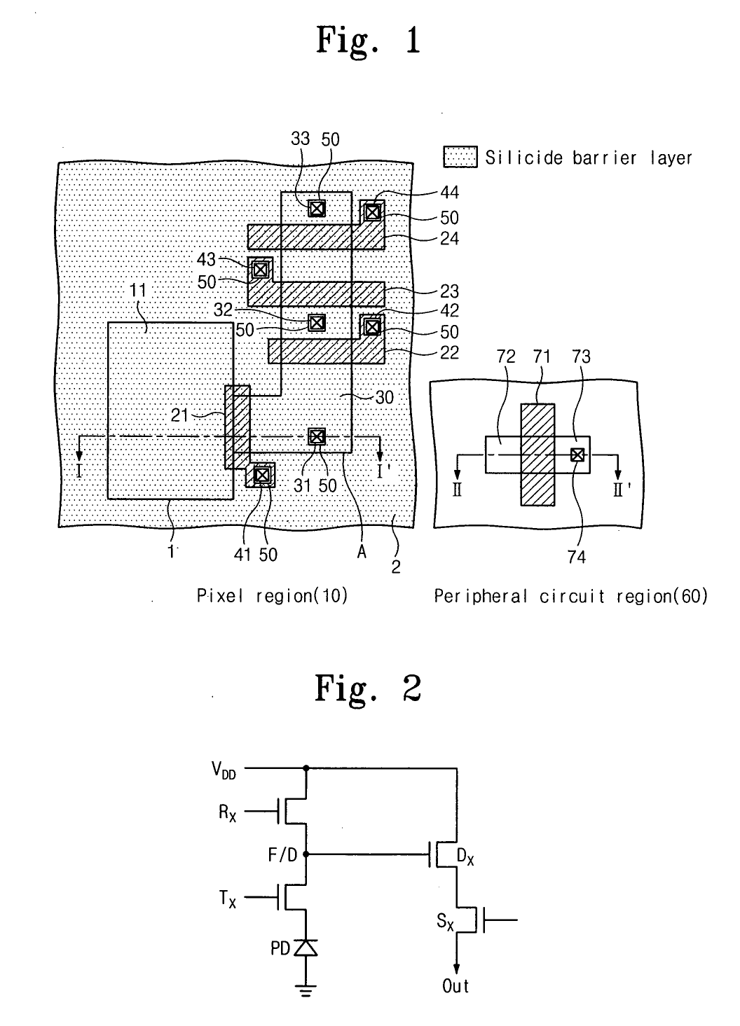

FIG. 1 is a plan view illustrating a CMOS image sensor in accordance with an embodiment of the invention.

Referring to FIG. 1, the CMOS image sensor in accordance with the present invention is comprised of a pixel region 10 for sensing incident light and generating an electrical signal, and a peripheral circuit region 60 for processing the electrical signal provided by the pixel region 10. A plurality of pixels of the pixel region 10 constitutes a pixel array. The pixel region 10 is configured to include a photo-receiving element 11 that is sensitive to light. The peripheral circuit 60 includes a correlated double-signaling (CDS) circuit for removing noise from the output signal of the pixel, and an analog-to-digital converter (ADC) for transforming the analog output signal of the pixel into a digital signal.

The photo-receiving element 11 of the pixel region 10 may be a photodiode. An active region ‘A’ connected to the photo-receiving element 11 includes at least a MOS transistor. According to the number of MOS transistors in the photo receiving element, the configuration of the pixel region 10 can be categorized as a 1-transistor, 3-transisture, or 4-transistor structure. The 1-transistor structure has a large ‘fill-factor’, where fill-factor represents an area ratio occupied by the photo-receiving element 11 as compared to the entire area of the pixel region 10. While light intensity increases with increased fill-factor of the photo-receiving element, the 1-transistor structure is disadvantageous in reducing noise and, for this reason, the 4-transistor structure has generally enjoyed more widespread use in current devices.

Whereas FIG. 1 shows a CMOS image sensor with the 4-transistor structure, the present invention is applicable to structures of any number of transistors. The 4-transistor pixel of the CMOS image sensor is formed to include transfer, reset, drive, and selection transistors, accompanying each with a transfer gate electrode 21, a reset gate electrode 22, a drive gate electrode 23, and a selection gate electrode 24.

FIG. 2 is an equivalent circuit view of the circuit of the pixel region shown in FIG. 1.

Referring to FIG. 2, the photodiode ‘PD’ used as the photo-receiving element 11 is connected with the transfer transistor ‘Tx’ and the reset transistor ‘Rx’ in series. A drain region of the reset transistor ‘Rx’ and a source region of the drive transistor ‘Dx’ are electrically connected and supplied with a voltage VDD. The drain region of the transfer transistor ‘Tx’ and the source region of the reset transistor ‘Rx’ correspond to a floating diffision region ‘F/D’. The floating diffusion region ‘F/D’ and the gate electrode of the drive transistor ‘Dx’ are electrically connected. The drive transistor ‘Dx’ is connected with the selection transistor ‘Sx’ in series. The electrical output signal Out is output at the drain region of the selection transistor ‘Sx’.

In the operation of the CMOS image sensor shown in FIG. 2, the reset transistor ‘Rx’ is first turned on to conduct a reset function for removing charge from the floating diffusion region ‘F/D’. After turning the reset transistor ‘Rx’ on, the transfer transistor ‘Tx’ is turned on to transfer signal charge by electron-hole pairs (EHPs), which are generated from light incident on the photodiode PD from an external source, toward the floating diffusion region ‘F/D’. Thereby, the potential of the floating diffusion region ‘F/D’ changes along with the potential at the gate electrode of the drive transistor ‘Dx’. Assuming the selection transistor ‘Sx’ is turned on in response to a selection signal, a signal representing the change in potential at the gate electrode of the drive transistor ‘Dx’ is transferred to the output terminal Out.

Contact holes are provided in the pixel area of the device to provide interconnections between circuit elements or with external circuits. Returning to FIG. 1, in the active region ‘A’ connected to the photo-receiving element 11, there are arranged a contact hole 32 through which a constant voltage is applied, a contact hole 31 for connection with the gate electrode 23 of the drive transistor ‘Dx’, and a contact hole 33 for outputting a signal therefrom. Further, contacts 41, 42, 43, and 44 may be respectively formed on the gate electrodes of the transistors, 21, 22, 23, and 24. While FIG. 1 shows the feature that the contact holes 41, 42, 43, and 44 are each provided onto the gate electrodes of the transistors 21, 22, 23, and 24 in the pixel region 10, it is permissible not to form the contact holes 41, 42, and 44 except the contact hole 43 of the drive gate electrode 23 coupled with the floating diffusion region ‘F/D’. In other words, the contact holes 41, 42, 44, may be formed in the specific pixel area among pluralities of the pixel regions connected with each other.

A silicide layer is disposed on a predetermined region of the pixel region 10. The pixel region 10 includes a first region 1 and a second region 2 in accordance with presence of the silicide layer. The first region 1 includes the photo-receiving element 11, which is covered by a silicide barrier layer for preventing the silicide layer from being formed thereon. The second region 2 represents the remaining area of the pixel region 10, including the gate electrodes 21, 22, 23, and 24 and the active region ‘A’. The silicide barrier layer is formed on a portion of the second region 2, and a silicide layer without the silicide barrier layer is formed on another portion of the second region 2. As such, in the territory of the pixel region 10, the silicide barrier layer is locally formed along a silicide barrier layer pattern 50. In the second region 2, there are boundaries between areas having the silicide barrier layer, and areas having the silicide layer without the silicide barrier layer. The silicide barrier layer pattern 50 is designed to define the areas which are to be formed with the silicide barrier layer.

In the second region 2, the silicide layer includes the contact holes 31, 32, and 33 formed in impurity diffusion regions corresponding to the source and drain regions of the transistors within the active region ‘A’. Namely, the silicide layer is disposed on the drain region at a side of the transfer gate electrode 21, or the drain regions at sides of the reset and selection gate electrodes 22 and 24. In the case of forming the contact holes 41˜44 on the gate electrodes 21˜24 of the transistors, the silicide layer may further be formed to include the contact holes 41˜44. Here, although the contact holes are variable in position and number by the number of the transistors, the present invention provides means to remove the silicide barrier layer from predetermined regions including the contact holes and to form the silicide layer thereon.

The peripheral circuit region 60, processing the electric output signal provided from the pixel region 10, includes pluralities of transistors. As the silicide barrier layer is not disposed on the transistors of the peripheral circuit region 60, the silicide layer can be deposited on a gate electrode 71, a source region 72, and a drain region 73 therein during the process of silicidation.

Now, the vertical structure of the CMOS image sensor by the invention will be described with reference to the figures.

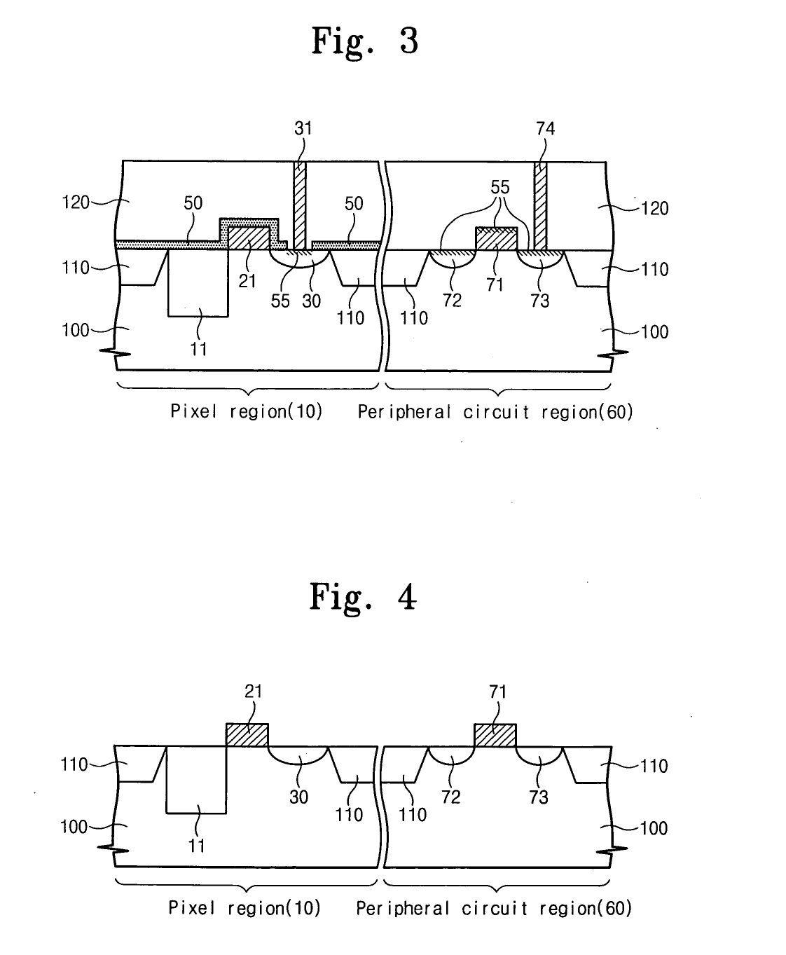

FIG. 3 is a sectional view taken along with the lines I-I′ and II-II′ of FIG. 1.

Referring to FIG. 3, field isolation films 110 are formed to define active regions of a semiconductor substrate 100. On the active regions are arranged various semiconductor devices. In the pixel region 10, there are formed the photo-receiving element 11 generating EHPs from light incident thereon, and the transfer gate electrode 21 and the floating diffusion region 30 arranged at a side of the photo-receiving element 11. The peripheral circuit region 60 is comprised of various semiconductor devices, for example, for removing noise from the output signal of the pixel region 10 or for converting an analog signal into a digital signal. However, the peripheral circuit region of FIG. 3 shows simply a single MOS transistor for the convenience of description.

An interlevel insulation film 120 is formed on the substrate 100, electrically isolating the semiconductor devices on the substrate 100. The contact holes 31 and 74 are formed to penetrate the interlevel insulation film 120. While FIG. 3 shows contact holes 31 and 74 on only the floating diffusion region 30 of the pixel region 10 and the drain region 73 of the peripheral circuit region 60, additional contact holes may be formed on the gate electrodes 21 and 71 of the transistors. The silicide layer 55 is formed on a region of the substrate 100 where the contact holes 31 and 74 are located. This selective formation of the silicide layer 55 is subject to the silicide barrier layer pattern 50, by which in the pixel region 10, the silicide layer 55 cannot be formed except a region where the contact 31 are located. In the peripheral circuit region 60, it is possible to form the silicide layer 55 on the source region 72, the drain region 73, and the gate electrode 71 without the silicide barrier layer.

As mentioned above, the silicide barrier layer pattern 50 is selectively provided in the pixel region 10 and the peripheral circuit region 60, but the silicide layer 55 is formed on the regions where the contact holes 31 and 74 are formed in both the pixel and peripheral circuit. Such a structural feature is formed in a processing method characterized by the invention, which will be understood through the following description.

FIGS. 4 through 8 are sectional views illustrating processing steps for fabricating the CMOS image sensor in accordance with an embodiment of the invention.

First, referring to FIG. 4, the field isolation films 110 are formed to define the active regions in the semiconductor substrate 100 of silicon. The field isolation films 110 may be completed by, after forming trenches from selectively etching the substrate 100, conducting a typical process for filling the trenches with an insulation material. On the semiconductor substrate 100 are formed pluralities of semiconductor elements. In the pixel region 10, there are formed the photo-receiving element 11 such as the photodiode for sensing light, and the transfer gate electrode 21 and the floating diffusion region 30 connected with the photo-receiving element 11. The transistor with the gate electrode 71, the source region 72, and the drain region 73 is formed in the peripheral circuit region 60.

Referring to FIG. 5, a silicide barrier layer 50′ is deposited on the substrate 100. The silicide barrier layer 50′ is provided to prevent silicidation between metal and silicon, and comprises, for example, a silicon nitride film. Further, an oxide film may be provided thereon to reduce mechanical stress caused by the presence of the silicon nitride film. The oxide film can comprises a type of thermal oxide film, e.g., a middle temperature oxide film. The silicide barrier layer 50′ is formed on the peripheral circuit region 60 as well as the pixel region 10.

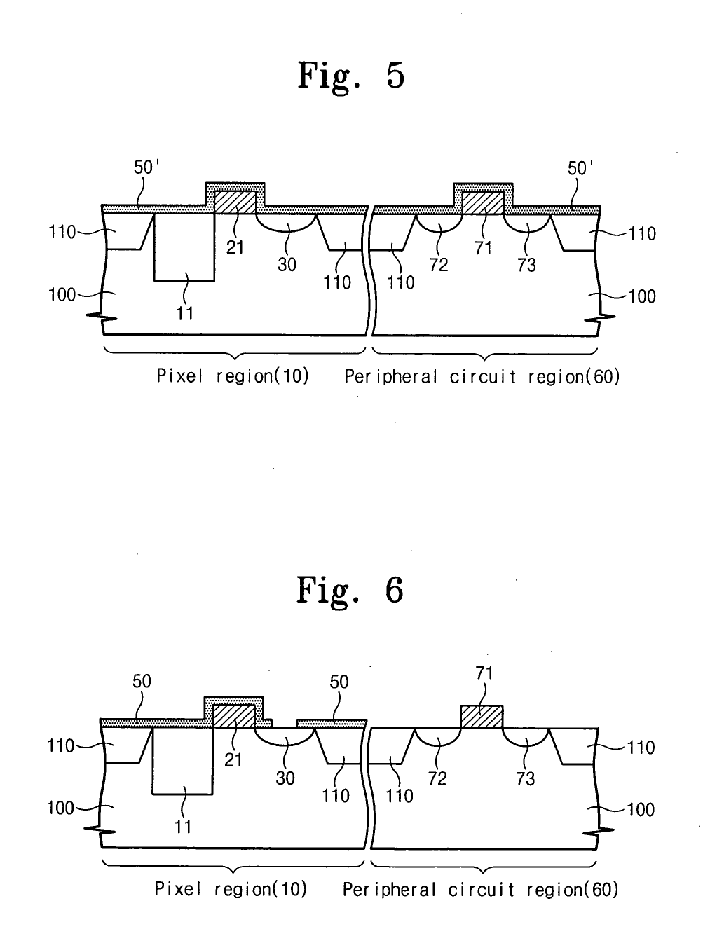

Referring to FIG. 6, the silicide barrier layer 50′ is patterned. For this, a photoresist pattern is arranged on the silicide barrier layer 50′ by means of a photographic process with a photoresist film and exposes a predetermined portion of the silicide barrier layer 50′. Using the photoresist pattern as an etching mask, the silicide barrier layer 50′ is selectively etched away to form the silicide barrier pattern 50. In the pixel region 10, the silicide barrier layer 50′ is partially removed in only regions corresponding to the contact holes. In the peripheral circuit region 60, the silicide barrier layer 50′ is removed from the gate electrode 71, the source region 72, and the drain region 73 in the active region.

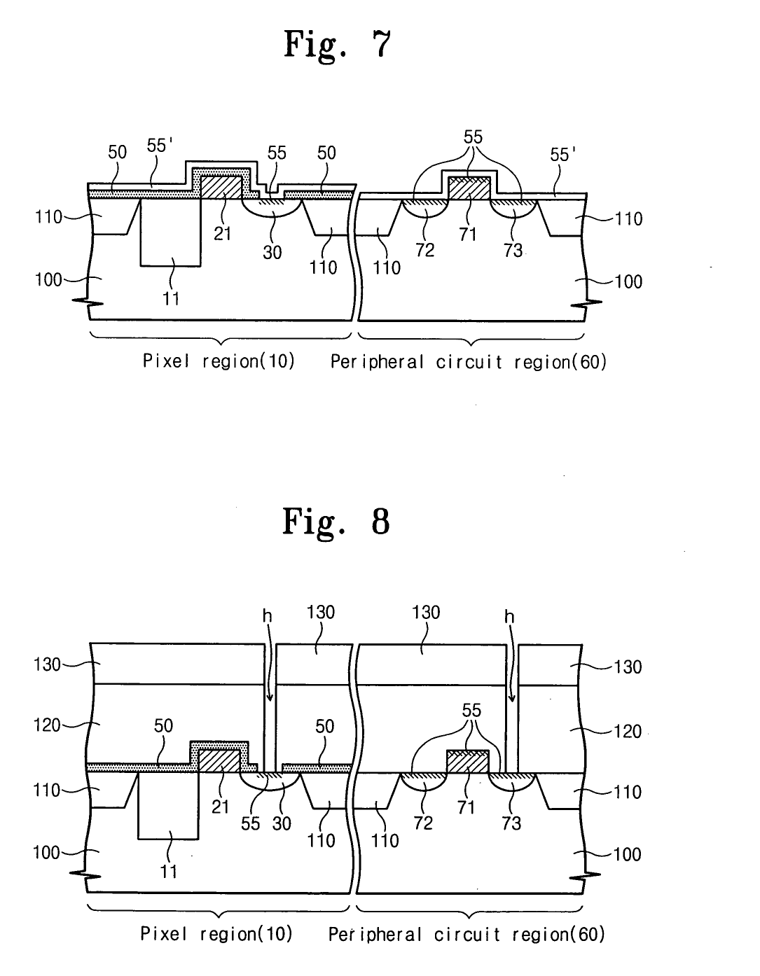

Referring to FIG. 7, a metal film 55′ is deposited on the substrate 100 so as to form the suicide layer. The metal film 55′ can comprise, for example, cobalt (Co), titanium (Ti), nickel (Ni), or tungsten (W), which can be deposited thereon by means of a sputtering process. After depositing the metal film 55′, a thermal process, e.g., rapid thermal process (RTP), is carried out to form the silicide layer 55 through a reaction between the metal film 55′ and the silicon of the gate electrode 71 or the substrate 100.

During this process, in the pixel region 10, the silicide layer 55 is formed only on regions where the silicide barrier layer 50′ is removed. In detail, as illustrated in FIG. 7, at the region for the contact hole on the floating diffusion region 30, the metal film 55′ reacts with the silicon of the exposed substrate 100 material and the silicide layer 55 is formed thereon. Further, although not shown, in the case of forming contact holes on the gate electrodes of the transfer and selection transistors shown in FIG. 1, polysilicon of the corresponding region reacts with the metal film and thereby the silicide layer 55 is formed thereon.

Meanwhile, in the peripheral circuit region 60, the silicide layer 55 is formed on all of the regions where the metal film contacts silicon material such as regions where the source region 72, the drain region 73, and the gate electrode 71 are formed. However, the silicide layer 55 is not be formed on the patterned regions where the silicide barrier layer 50′ remains and regions where it is incapable of reacting with silicon even without the silicide protection layer 50′, for example a region where the metal film 55′ is deposited directly on the field isolation film 110.

Referring to FIG. 8, any metal film 55′ remaining thereon is removed from the substrate 100 and the interlevel insulation film 120 is formed on the resulting structure. Holes ‘h’ are formed through the interlevel insulation film 120 so as to form electrical interconnections among devices. The holes h are formed by forming a photoresist pattern 130 on the interlevel insulation film 120 and then selectively etching the interlevel insulation film 120 using the photoresist pattern 130 as an etching mask. After completing the holes h, the holes h are filled with a conductive material and then a conventional process is carried out to form metal interconnections.

The interlevel insulation film 120 typically comprises oxide and the holes h for the contacts may be formed by means of a dry etching process to the oxide film. Such a dry etching process is carried out on the pixel region 10 and the peripheral circuit region 60 at the same time. According to the invention, the regions for the contact holes in the pixel region 10 are comprised only of the interlevel insulation film 120 because the silicide barrier layer 50′ has been removed therefrom.

In a case where the silicide barrier layer 50′ remains on the device regions below the contact holes, the target film to be etched away is the interlevel insulation film 120 only in the peripheral circuit region 60 while the target film to be etched away is the remaining silicide barrier layer 50′ as well as the interlevel insulation film 120 in the pixel region 10. When the silicide barrier layer 50′ contains a nitride film, the nitride film is etched away from the pixel region 10 in addition to the interlevel insulation film 120 of oxide in order to form the holes h. Here, as the nitride film is different from the oxide film in etching selectivity, the semiconductor substrate 100 of the peripheral circuit region 60 can become over-etched or over-recessed, and is thus damaged, during removal of the nitride film in the pixel region 10, after the oxide interlevel insulation film 120 etched away from the peripheral circuit region 60. Moreover, the field isolation film 110 adjacent to the holes h can also become over-recessed and damaged. However, according to the present invention, since the silicide barrier layer 50′ is preliminarily removed from the substrate and devices in regions where the holes h are formed, it is possible to prevent recess damage from occurring on the substrate 100 or on the field isolation film 110. On the other hand, the effect on the operation of the CMOS image sensor when the silicide barrier layer 50′ is removed from specific regions of the pixel region 10 should be considered.

In the CMOS image sensor, formation of the silicide barrier layer 50′ on the pixel region 10 prevents the silicide layer 55 from being generated thereon. Even though a silicide layer 55 is beneficial for reducing resistance, the reason for preventing the silicide layer 55 from being formed on the pixel region 10, in particular on photo-diode 11, is because the presence of a silicide layer in this region 10 can cause various malfunctions and degradation of optical characteristics of the photo-receiving elements such as the photodiode. However, if such malfunctions can be prevented, it can be permissible to form the silicide layer 55 on the pixel region 10.

As aforementioned, considering that the pixel region 10 includes two types of regions: that is, a first region requiring the presence of the silicide barrier layer 50′; and a second region where the silicide barrier layer 50′ is not required, or not desired, the silicide barrier layer 50′ is formed in the first region while selectively formed in the second region. For instance, it is essential for the region, in which the photo-receiving element 11 is present, to have the silicide barrier layer 50′, but, it is not essential for the regions, in which the contact holes for the transistors are arranged, to have the silicide barrier layer 50′ because a silicide layer 55 is desired in the contact hole regions. Further, the field isolation films 110 defining the active regions do not necessarily require the silicide barrier layer 50′. However, in the embodiment shown, the silicide layer 55 is nevertheless not formed on the field isolation films 110 due to the presence of the silicide barrier layer 50′ on the films 110 in the pixel region 10.

In this manner, after removing the silicide barrier layer 50′ from the predetermined regions of the pixel region 10, subsequent processing steps for device formation are simultaneously carried out on the pixel region 10 and the peripheral circuit region 60, so that it is possible to retain uniform quality in the processed target films.

Further, according to the present inventions there is no need for an additional processing step for removing the silicide barrier layer 50′ from the predetermined regions of the pixel region 10. It is possible to remove the silicide barrier layer 50′ from the predetermined regions of the pixel region 10 as well as from the peripheral circuit region 60 at the same time. This is accomplished by simply modifying the pattern of the exposing mask used in the photolithography step, which is efficient in the procedure of fabricating the CMOS image sensor without causing addition processing delay.

In addition, contact resistance in the pixel region 10 is reduced, since the silicide layer 55 is formed after removing the silicide barrier layer 50′, which provides the effect of lowering the operation voltage VDD applied to the floating diffusion region 30.

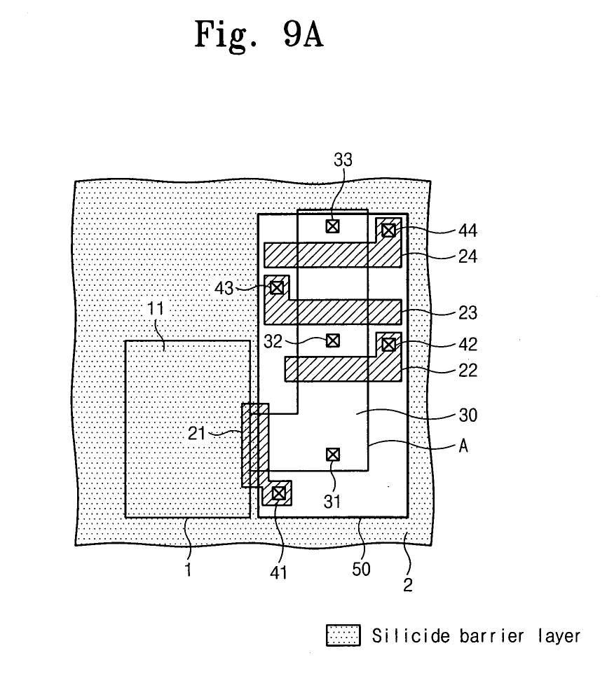

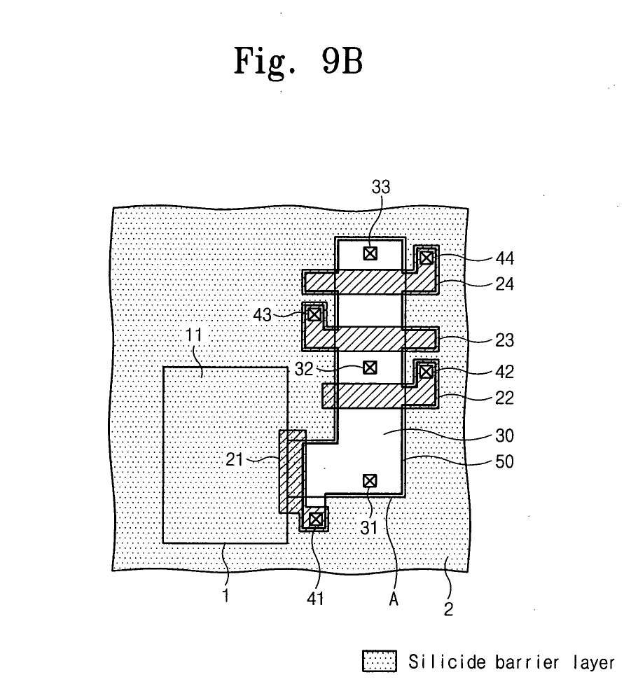

FIGS. 9A and 9B are plan views illustrating CMOS image sensors in accordance with other embodiments of the invention.

Referring to FIGS. 9A and 9B, the pixel region 10 is sectioned into the first region 1 and the second region 2. The first region 1 includes the photo-receiving element 11, being covered by the silicide barrier layer in order to prevent the silicide layer 55. The second region 2 corresponds to the remainder of the pixel region 10 excluding the first region 1, in which the silicide barrier layer is partially formed on the predetermined region corresponding to the silicide barrier pattern 50 while the silicide layer is formed on the remainder of the region. In FIGS. 9A and 9B, the silicide barrier pattern 50 is configured to define the boundaries of the regions on which the silicide barrier layer is formed.

In the second region 2, the silicide layer is formed on a unified region including the contact holes 31, 32, 33, 34, 41, 42, 43, and 44. As illustrated in FIG. 9A, the silicide layer is formed over the region including the active region ‘A’ and the gate electrodes 21, 22, 23, and 24, except the contact holes 31, 32, 33, 34, 41, 42, 43, and 44. On the other hand, in the FIG. 9B embodiment, the silicide layer is partially formed on the active region ‘A’ and the gate electrodes 21, 22, 23, and 24. Namely, the silicide layer is formed along the silicide barrier pattern 50 on the regions where metal can react with silicon among the regions from which the silicide barrier layer is removed. As aforementioned, it is possible not to form the contact holes 41˜44 partially or entirely on the gate electrodes 21˜24. In this case, the silicide layer may be arranged only on the region including the active region ‘A’ or parts of the contact holes 41˜44 of the gate electrodes 21˜24. As such, the processing steps are easily carried out when the silicide layer is formed on the unified region. In other words, when the silicide barrier layer is locally removed from the second region 2 before forming the silicide layer, it is advantageous for the silicide barrier layer to be removed in a unified region including all the contact holes 31˜33 and 41˜44 if considering the small sizes of the contact holes 31˜33 and 41˜44.

After removing the silicide barrier layer from the second region 2, the silicide layer may be formed on the corresponding regions through subsequent processing steps. Therefore, the silicide barrier layer excludes the regions, which would cause an operational problem with the silicide layer, from becoming silicidized. For instance, as aforementioned, the presence of a silicide layer on the photo-receiving element 11 may degrade operational characteristics of the device. Other structural forms of the silicide barrier layer, different from those shown in FIGS. 9A and 9B, are equally applicable to the present invention.

Meanwhile, while the aforementioned embodiments describe preventing silicidation of features in the pixel region other than those corresponding to the contact holes, the invention is not restricted thereto. Beyond this, the present invention is equally applicable, to a case, such as the case where disagreement of processing target films would occur between the pixel region and the peripheral circuit region because of presence of the silicide barrier layer.

As stated above, the invention has advantages as follows.

First, it is possible to keep films, which are to be etched away, uniform in quality over the pixel region and peripheral circuit region by locally removing the silicide barrier layer from the pixel region, in proceeding with a specific process such as an etching process. Thus, there damage to the substrate due to an excessive etching in the peripheral circuit region, by different qualities of films to be etched away in the pixel region and peripheral circuit region can be prevented, while conducting an etching process on the pixel.

Second, there is no need for an additional processing step for locally removing the silicide barrier layer from the pixel region. As the silicide barrier layer is simultaneously patterned both in the pixel region and the peripheral circuit region while removing the silicide barrier layer from additional regions, there is no procedural delay in the fabrication process for the CMOS image sensor.

Third, since the silicide layer is formed after locally removing the silicide barrier layer from the regions where the contact holes are formed, the contact resistance is reduced so that lower operation voltage can be realized.

While this invention has been particularly shown and described with references to preferred embodiments thereof, it will be understood by those skilled in the art that various changes in form and details may be made herein without departing from the spirit and scope of the invention as defined by the appended claims.

What is claimed is:

1. A method of fabricating a CMOS image sensor comprising:
providing a substrate having a pixel region and a peripheral circuit region;
forming a photo-receiving element and at least one transistor on the pixel region of the substrate and forming a transistor on the peripheral circuit region of the substrate;
forming a silicide barrier layer pattern to cover a region where the photo-receiving element is formed;
forming a silicide layer on a predetermined region of the substrate;
forming an interlevel insulation film on the silicide barrier layer pattern; and
forming at least one contact hole penetrating the interlevel insulation film, the at least one contact hole exposing a predetermined region of the silicide layer.

2. The method according to claim 1, wherein the forming the silicide barrier layer pattern in the pixel region comprises:
depositing a silicide barrier layer on the substrate; and
removing the silicide barrier layer formed in at least a region where the at least one contact hole is formed.

3. The method according to claim 1, wherein forming the silicide barrier layer pattern in the pixel region comprises:
depositing a silicide barrier layer on the substrate; and
removing the silicide barrier layer formed in at least a region where the at least one contact hole is formed in a unified portion.

4. The method according to claim 1, wherein the photo-receiving element is a photodiode.

5. The method according to claim 1, wherein forming the silicide barrier layer pattern in the peripheral circuit region comprises:
depositing a silicide barrier layer on the substrate; and
removing the silicide barrier layer in an active region and a region where a gate electrode of the transistor is formed.

6. The method according to claim 1, wherein the silicide barrier layer pattern includes a nitride film.

7. A method of fabricating a CMOS image sensor comprising:
providing a substrate having a pixel region and a peripheral circuit region;
forming a transfer gate electrode on the substrate of the pixel region;
forming a photo-receiving element at a side of the transfer gate electrode;
forming a floating diffusion region at a side of the transfer gate electrode opposite the photo-receiving element;
forming a silicide barrier layer pattern on the photo-receiving element;
forming a first silicide layer on a portion of the floating diffusion region; and
forming an interlevel insulating layer on the silicide barrier layer pattern and the transfer gate electrode, the interlevel insulating layer having a contact hole exposing a portion of the first silicide layer.

8. The method according to claim 7, wherein the photo-receiving element and the floating diffusion region are formed in the substrate of the pixel region.

9. The method according to claim 7, wherein the silicide barrier layer pattern extends across the upper surface of the transfer gate electrode.

10. The method according to claim 7, further comprising forming a gate dielectric layer between the transfer gate electrode and the substrate.

11. The method according to claim 7, wherein the silicide barrier layer pattern comprises a silicon nitride film.

12. The method according to claim 7, further comprising forming a second silicide layer on the transfer gate electrode.

13. The method according to claim 7, further comprising forming at least one transistor on the peripheral circuit region, the transistor having a drain, a source, and a gate electrode.

14. The method according to claim 13, further comprising forming a third silicide layer on surfaces of the source, drain, and gate electrodes.

15. A CMOS image sensor comprising:
a substrate having a pixel region with a first and a second region and a peripheral circuit region;
a photo-receiving element on the first region of the substrate;
at least one transistor including an active region connected to the photo-receiving element on the second region of the substrate;
a silicide barrier layer formed on the first region of the substrate;
a silicide layer formed on a portion of the second region of the substrate;
an interlevel insulation layer covering the silicide barrier layer and the first and second regions of the substrate and having at least one contact hole penetrating the interlevel insulation layer, the contact hole exposing a portion of the silicide layer.

16. The CMOS image sensor according to claim 15, wherein the contact hole is formed in a impurity diffusion region of the transistor in the active region.

17. The CMOS image sensor according to claim 15, wherein the at least one contact hole is formed on a gate electrode of the transistor.

18. The CMOS image sensor according to claim 15, wherein the at least one contact hole is formed in plurality and the silicide layer is formed in plural separated regions of the second region.

19. The CMOS image sensor according to claim 15, wherein the at least one contact holes is formed in plurality and the silicide layer is formed in an unified region that includes the plurality of contact holes.

20. The CMOS image sensor according to claim 15, wherein the photo-receiving element is a photodiode.

21. The CMOS image sensor according to claim 15, further comprising at least one transistor processing a signal that is transferred from the pixel region in the peripheral circuit region.

22. The CMOS image sensor according to claim 21, wherein the silicide layer in the peripheral circuit region is formed in an active region and a region where a gate electrode of the transistor is formed.

23. The CMOS image sensor according to claims 15, wherein the silicide barrier layer comprises a nitride film.

24. A CMOS image sensor comprising:
a substrate having a pixel region and a peripheral circuit region;
a transfer gate electrode on the substrate of the pixel region;
a photo-receiving element at a side of the transfer gate electrode;
a floating diffusion region at a side of the transfer gate electrode opposite the photo-receiving element;
a silicide barrier layer pattern on the photo-receiving element;
a first silicide layer on a portion of the floating diffusion region; and
an interlevel insulating layer on the silicide barrier layer pattern and the transfer gate electrode, the interlevel insulating layer having a contact hole exposing a portion of the first silicide layer.

25. A CMOS image sensor according to claim 24, wherein the photo-receiving element and the floating diffusion region are disposed in the substrate of the pixel region.

26. A CMOS image sensor according to claim 24, wherein the silicide barrier layer pattern extends across the upper surface of the transfer gate electrode.

27. A CMOS image sensor according to claim 24, further comprising a gate dielectric layer between the transfer gate electrode and the substrate.

28. A CMOS image sensor according to claim 24, wherein the silicide barrier layer pattern comprises a silicon nitride film.

29. A CMOS image sensor according to claim 24, further comprising a second silicide layer on the transfer gate electrode.

30. A CMOS image sensor according to claim 24, further comprising at least one transistor on the peripheral circuit region, the transistor having a drain, a source, and a gate electrode.

31. A CMOS image sensor according to claim 30, further comprising a third silicide layer on surfaces of the source, drain, and gate electrodes.
